(19) United States
(12) Patent Application Publication
(10) Pub. No.: US 2014/0088897 A1
(43) Pub. Date: Mar. 27, 2014

(54) Computer Implemented Method for Diagnositc Analytics for Battery Life Management

(71) Applicant: NEC LABORATORIES AMERICA, INC., Princeton, NJ (US)

(72) Inventors: Ratnesh Sharma, Fremont, CA (US); Krishnamurthy Dvijotham, Seattle, WA (US)

(73) Assignee: NEC LABORATORIES AMERICA, INC., Princeton, NJ (US)

(21) Appl. No.: 14/038,530

(22) Filed: Sep. 26, 2013

Related U.S. Application Data
(60) Provisional application No. 61/705,909, filed on Sep. 26, 2012.

(51) Int. Cl. G01R 31/36; G06F 17/50

(52) U.S. Cl. CPC G01R 31/3606; G06F 17/5018
USPC 702/63

(57) ABSTRACT

A computer implemented method combines a simplified equivalent circuit model with a model capturing the variation of the circuit parameters. The components of the equivalent circuit model depend on the internal battery state, and the parameters of the model encode this dependence. The invention then uses actual operational data capturing various modes of operation of the battery and different discharge rates to fit the model parameters (rather than controlled laboratory tests used in previous work). Once this analysis is done (offline), the model can be used in an online phase to adjust estimates of the internal battery state as the battery is operating.

This application claims the benefit of U.S. Provisional Application No. 61/705,909 entitled “Diagnostic Analytics for Battery Life Management”, filed Sep. 26, 2012, of which the contents are incorporated herein by reference.

### BACKGROUND OF THE INVENTION

The present invention relates generally to battery life management and, more particularly, to a computer implemented method for diagnostic analytics for battery life management.

Batteries are complex electrochemical systems with poorly understood charge/discharge dynamics. When used as part of a sophisticated energy management system, particularly one that includes intermittent renewable generation, batteries are dynamically charged and discharged based on the availability of renewable generation, grid tariff and load. Further, when such a system is online, any estimation of the internal state needs to be based only on the measurable variables: Battery current and voltage. The present invention attempts to build a battery model that can infer the internal state of the battery from just online current and voltage measurements.

Various battery models have be proposed and tested in literature for different applications. There have been models based on the actual physical processes of the system, more abstract models that use equivalent circuit representations of the battery and black box models like neural networks and fuzzy logic. However, none of these approach simultaneously satisfy the following requirements (which are critical to developing an energy management system like the one here at NECLA): a) Being easy to fit (computationally and statistically) from observed variables online, as the battery is being used, b) Working across various battery states and c) Being interpretable.

Accordingly, there is a need for a method for battery life management that improves upon prior techniques.

### BRIEF SUMMARY OF THE INVENTION

In an aspect of the present invention, a computer implemented method for battery life management with diagnostic analytics includes combining an equivalent circuit model of a battery and an offline model capturing variation of circuit parameters of the battery, components of the equivalent circuit model depending on determined internal state of the battery and the parameters of the offline model taking into account the equivalent circuit model; employing actual operational data, in an online data operational mode, for capturing various modes of operation of the battery and different discharge rates to fit the parameters of the offline model; and using a completed analysis from above to enable the offline model to be used in an online phase to adjust estimates of the internal battery state as the battery is operating.

In a similar aspect of the present invention, a computer system configured with instructions for battery life management with diagnostic analytics includes combining an equivalent circuit model of a battery and an offline model capturing variation of circuit parameters of the battery, components of the equivalent circuit model depending on determined internal state of the battery and the parameters of the offline model taking into account the equivalent circuit model; employing actual operational data, in an online data operational mode, for capturing various modes of operation of the battery and different discharge rates to fit the parameters of the offline model; and using a completed analysis from above to enable the offline model to be used in an online phase to adjust estimates of the internal battery state as the battery is operating.

These and other advantages of the invention will be apparent to those of ordinary skill in the art by reference to the following detailed description and the accompanying drawings.

### BRIEF DESCRIPTION OF THE DRAWINGS

FIG. 1 is a block diagram of diagnostic analytics for battery life management, in accordance with the invention;

FIG. 2 is block diagram further detailing FIG. 1, in accordance with the invention; and

FIG. 3 is a diagram showing an exemplary computer to perform the inventive battery life management.

### DETAILED DESCRIPTION

The invention is directed to a novel computer implemented method battery life management with diagnostic analytics that combines a simplified equivalent circuit model with a model capturing the variation of the circuit parameters. The components of the equivalent circuit model depend on the internal battery state, and the parameters of the model encode this dependence. Then in n an online data operational mode, the invention uses actual operational data capturing various modes of operation of the battery and different discharge rates to fit the model parameters (rather than controlled laboratory tests used in previous work). Once this analysis is done (offline), the model can be used in an online phase to adjust estimates of the internal battery state as the battery is operating.

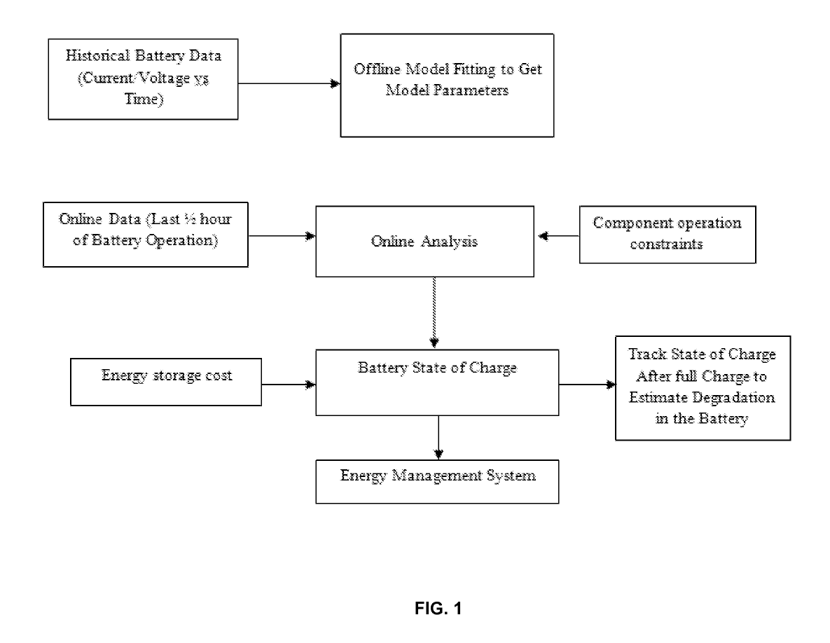

FIG. 1 is a block diagram of diagnostic analytics for battery life management, in accordance with the invention. As shown, historical battery data, e.g., as current/voltage versus time, are used in an offline model fitting to determine model battery for a simplified equivalent circuit model. Online battery data, such as data from prior half hour of battery operation and component operation constraints, are employed in an online analysis. An energy storage cost and the online analysis are accounted for in a battery state of charge that is used to track state of charge after full charge to estimate degradation in the battery. The overall energy management system utilizes the battery state of charge determination.

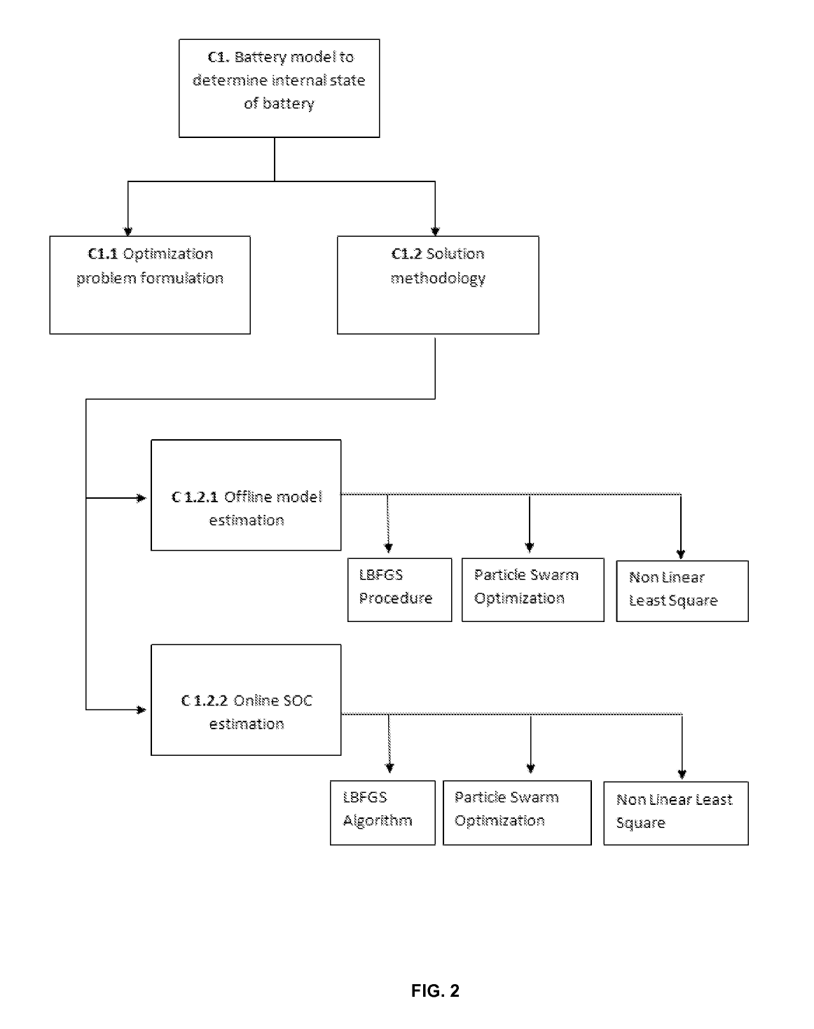

Turning now to FIG. 2, there is shown a block diagram further detailing key aspects of FIG. 1. The battery model to determine the internal state of the battery C1 is used for an optimization problem formulation C1.1 and a solution methodology. The solution methodology C1.2 entails an offline model estimation C1.2.1 and an online state of charge estimation C1.2.2. The offline model estimation includes a limited-memory Broyden-Fletcher-Goldfarb-Shanno LBFGS procedure, a particle swarm optimization and nonlinear least square procedure. The online state of charge estimation also includes an LBFGS procedure, a particle swarm optimization and non-linear least square procedure.

The battery model fitting procedure (C.1) to determine the internal state of the battery is a novel aspect of the present invention. The model parameters are fitted using actual data collected from the battery in operation. This enables the invention to identify and deal with dynamic operational modes of the battery, which may not be visible in the controlled laboratory tests done by the manufacturer. The invention models the fitting as an optimization procedure, that compares closed circuit voltage predictions from the model with actual voltage measurements, and tunes the model parameters so as to minimize the difference between these two.

A discharge event V consists of time series {(t, I [symbol] (t), V [symbol] (t)} of current and voltage measurements taken at discrete points in time t=t₁; t₂; ::: , t_{N}. For simplicity, we shall assume that all discharge events have measurements taken at these fixed points in time since the beginning of discharge, although this is not a requirement. Let θ denote the model parameters as before and K⁰=[K⁰; Qₐ⁰; Q_{b}⁰]∈R³ be the initial stored charge and charges on the two capacitors. Given a particular discharge event, [symbol] we can define the cumulative error for given model parameters θ and initial state Q⁰ as follows:

$$Err ( D , θ , {Q}^{0} ) = {\sum }_{i = 1}^{N} \frac{1}{N} \frac{{( \hat{V} ( D , {t}_{i} ) - {V}_{D} ( {t}_{i} ) )}^{2}}{2} \\ \begin{matrix}\hat{V} ( D , t ) = {V}_{OC} ( S ( D , t ) ) - {R}_{s} ( S ( D , t ) , θ ) {I}_{D} ( t ) - \\ \frac{{Q}_{a} ( D , t )}{{C}_{p }^{a} ( S ( D , t ) , θ )} - \frac{{Q}_{b} ( D , t )}{{C}_{p}^{b} ( S ( D , t ) , θ )}\end{matrix} \\ \frac{d κ ( D , t )}{d t} = - \frac{{{I}_{0} ( \frac{{I}_{D} ( t )}{{I}_{0}} )}^{α}}{C} \\ S ( D , t ) = {I}_{r} \frac{κ C}{{{I}_{0} ( \frac{{I}_{r}}{{I}_{0}} )}^{α}} \frac{1}{{C}_{r}} \\ \frac{d {Q}_{a} ( D , t )}{d t} = {C}_{p}^{a} ( S ( D , t ) ) \frac{d ( {I}_{D} ( t ) {R}_{p}^{a} ( S ( D , t ) , θ ) )}{d t} \\ \frac{d {Q}_{b} ( D , t )}{d t} = {C}_{p}^{b} ( S ( D , t ) ) \frac{d ( {I}_{D} ( t ) {R}_{p}^{b} ( S ( D , t ) , θ ) )}{d t} \qquad ( 1 )$$

Where S is the state of charge of the battery from the stored charge K, I represents current, V represents voltage, Iᵣ is a rated discharge current, R is resistance, and C is capacitance, Cᵣ is rated capacitance Assuming that the interval between successive measurements tᵢ, tᵢ₊₁ is small, the invention can solve the above cumulative errors in closed form over (tᵢ, tᵢ₊₁) and simply works with the integrated discrete time dynamics, which makes the simulation a lot faster overall.

The optimization problem formulation (C1.1) for offline model estimation and online state of charge estimation is a novel aspect of the present invention. Also, the solution methodology (C.1.2) involves the offline model estimation (C1.2.1) and the online state of charge estimation (C.1.2.2) are novel aspects of the invention.

The offline model estimation C1.2.1 entails optimization technique that uses the LBFGS optimization procedure and adjoint method to compute model parameters and initial state Q⁰ based on the following relationship:

$$θ , {Q}_{1}^{0} , {Q}_{2}^{0} , … , {Q}_{K}^{0} {\sum }_{i}^{ } \frac{1}{K} Err ( {D}_{i} , θ , {Q}_{i}^{0} ) .$$

The online state of charge SOC estimation entails a model that solves the following optimization problem:

$${min}_{{Q}^{0}} Err ( {D}_{p} , θ , {Q}^{0} ) ,$$

where Err ( [symbol] ᵢ, θ, Qᵢ⁰) represents gradients of error with respect to θ, Qᵢ⁰ and is computed using the adjoint method, D_{P} is the immediately preceding discharge profile (corresponding to the last T minute of operation). The invention updates every T minutes, looking at voltage and current over the last T minute to get a best fit to get a best fit estimate of the state of charge Q⁰ at the beginning of the discharge period.

The above described procedure enables a battery life management system that is capable of performing analysis using only operational data, without having to interfere with the charging and discharging schedules of the battery. The model works across different battery discharge rates and battery states, and is computationally inexpensive, Another advantage is the inventive model is easy to fit and interpret computationally and statistically from observed variables online.

The invention may be implemented in hardware, firmware or software, or a combination of the three. Preferably the invention is implemented in a computer program executed on a programmable computer having a processor, a data storage system, volatile and non-volatile memory and/or storage elements, at least one input device and at least one output device.

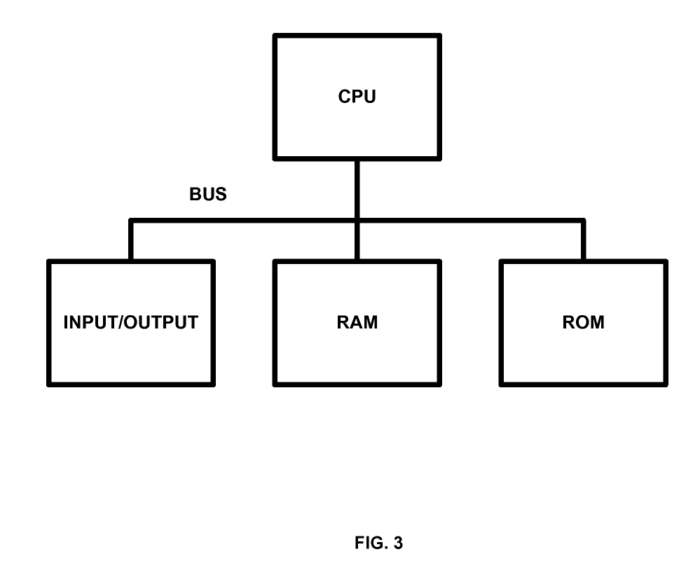

By way of example, a block diagram of a computer to support the system is discussed next in FIG. 3. The computer preferably includes a processor, random access memory (RAM), a program memory (preferably a writable read-only memory (ROM) such as a flash ROM) and an input/output (I/O) controller coupled by a CPU bus. The computer may optionally include a hard drive controller which is coupled to a hard disk and CPU bus. Hard disk may be used for storing application programs, such as the present invention, and data. Alternatively, application programs may be stored in RAM or ROM. I/O controller is coupled by means of an I/O bus to an I/O interface. I/O interface receives and transmits data in one of or combination of analog or digital form over one or a number of communication links such as a serial link, local area network, wireless link, optical link and parallel link. Optionally, a display, a keyboard and a pointing device (mouse) may also be connected to I/O bus. Alternatively, separate connections (separate buses) may be used for I/O interface, display, keyboard and pointing device. Programmable processing system may be preprogrammed or it may be programmed (and reprogrammed) by downloading a program from another source (e.g., a floppy disk, CD-ROM, or another computer).

Each computer program is tangibly stored in a machine-readable storage media or device (e.g., program memory or magnetic disk) readable by a general or special purpose programmable computer, for configuring and controlling operation of a computer when the storage media or device is read by the computer to perform the procedures described herein. The inventive system may also be considered to be embodied in a computer-readable storage medium, configured with a computer program, where the storage medium so configured causes a computer to operate in a specific and predefined manner to perform the functions described herein.

From the foregoing it can also be appreciated that the inventive battery management would benefit operation of energy management systems. In order to make optimal decisions about when to discharge/charge the battery (based on fluctuations in grid tariff/solar power etc.), the inventive energy management system requires good online estimates of the battery state. This can directly lead to cost savings and also in incorporating battery life into the management system, ensuring that the system is operated in such a way that the battery life is maximized, while minimizing energy costs. Additional supporting details for the present invention are in the Appendix to the Application, appended hereto.

The foregoing is to be understood as being in every respect illustrative and exemplary, but not restrictive, and the scope of the invention disclosed herein is not to be determined from the Detailed Description, but rather from the claims as interpreted according to the full breadth permitted by the patent laws. It is to be understood that the embodiments shown and described herein are only illustrative of the principles of the present invention and that those skilled in the art may implement various modifications without departing from the scope and spirit of the invention. Those skilled in the art could implement various other feature combinations without departing from the scope and spirit of the invention.

1. A computer implemented method for battery life management with diagnostic analytics, the computer implemented method comprising the steps of:
i) combining an equivalent circuit model of a battery and an offline model capturing variation of circuit parameters of the battery, components of the equivalent circuit model depending on determined internal state of the battery and the parameters of the offline model taking into account the equivalent circuit model;
ii) employing actual operational data, in an online data operational mode, for capturing various modes of operation of the battery and different discharge rates to fit the parameters of the offline model; and
iii) using a completed analysis from step ii) to enable the offline model to be used in an online phase to adjust estimates of the internal battery state as the battery is operating.

2. The computer implemented method of claim 1, wherein for the offline model taking into account a particular discharge event D, a cumulative error for given parameters θ and initial state Q⁰ of offline model parameters θ and initial state Q⁰ is based on
$$Err ( D , θ , {Q}^{0} ) = {\sum }_{i = 1}^{N} \frac{1}{N} \frac{{( \hat{V} ( D , {t}_{i} ) - {V}_{D} ( {t}_{i} ) )}^{2}}{2} \\ \begin{matrix}\hat{V} ( D , t ) = {V}_{OC} ( S ( D , t ) ) - {R}_{s} ( S ( D , t ) , θ ) {I}_{D} ( t ) - \\ \frac{{Q}_{a} ( D , t )}{{C}_{p }^{a} ( S ( D , t ) , θ )} - \frac{{Q}_{b} ( D , t )}{{C}_{p}^{b} ( S ( D , t ) , θ )}\end{matrix} \\ \frac{d κ ( D , t )}{d t} = - \frac{{{I}_{0} ( \frac{{I}_{D} ( t )}{{I}_{0}} )}^{α}}{C} \\ S ( D , t ) = {I}_{r} \frac{κ C}{{{I}_{0} ( \frac{{I}_{r}}{{I}_{0}} )}^{α}} \frac{1}{{C}_{r}} \\ \frac{d {Q}_{a} ( D , t )}{d t} = {C}_{p}^{a} ( S ( D , t ) ) \frac{d ( {I}_{D} ( t ) {R}_{p}^{a} ( S ( D , t ) , θ ) )}{d t} \\ \frac{d {Q}_{b} ( D , t )}{d t} = {C}_{p}^{b} ( S ( D , t ) ) \frac{d ( {I}_{D} ( t ) {R}_{p}^{b} ( S ( D , t ) , θ ) )}{d t} \qquad ( 1 )$$
where the discharge event D consists of time series {(t, I_{D}(t), V_{D}(t)} of current and voltage measurements taken at discrete points in time t=t₁, t₂, . . . , t_{N}, θ denotes model parameters, S is a state of charge of the battery from the stored charge K, I represents current, V represents voltage, Iᵣ is a rated discharge current, R is resistance, C is capacitance, and Cᵣ is a rated capacitance, and Q⁰=[S⁰; Qₐ⁰; Q_{b}⁰]∈R³ is the initial S and charges on two capacitors.

3. The computer implemented method of claim 2, wherein assuming that the interval between successive measurements tᵢ,tᵢ₊₁ is small, the invention can solve the above cumulative errors in closed form over (tᵢ, tᵢ₊₁) and simply works with the integrated discrete time dynamics, which makes the simulation a lot faster overall.

4. The computer implemented method of claim 1, wherein the internal state of the battery comprises an optimization procedure that compares closed circuit voltage predictions from the model with actual voltage measurements and tunes the parameters of the model to minimize the difference between these two.

5. The computer implemented method of claim 1, wherein the offline model comprises using a collection of discharge profiles {Dᵢ}ᵢ₌₁^{K}, collected from actual operational data, to identify model parameters θ by solving an optimization problem based on
$${θQ}_{1}^{0} , {Q}_{2}^{0} , … , {Q}_{K}^{0} {\sum }_{i}^{ } \frac{1}{K} Err ( {D}_{i} , θ , {Q}_{i}^{0} )$$
where Err ( [symbol] ᵢ, θ, Qᵢ⁰) represents gradients of error with respect to θ, Qᵢ⁰ and is computed using an adjoint method, [symbol] _{P} is the immediately preceding discharge profile corresponding to a last T minute of operation.

6. The computer implemented method of claim 1, wherein the online data operational mode comprises an online state of charge SOC estimation entails a model that solves the following optimization problem:
$${min}_{{Q}^{0}} Err ( {D}_{p} , θ , {Q}^{0} ) ,$$
where Err ( [symbol] ᵢ, θ, Qᵢ⁰) represents gradients of error with respect to θ, Qᵢ⁰ and is computed using an adjoint method, [symbol] _{P} is the immediately preceding discharge profile corresponding to the last T minute of operation.

7. A computer system configured with instructions for battery life management with diagnostic analytics, the computer system carrying out the following:
i) combining an equivalent circuit model of a battery and an offline model capturing variation of circuit parameters of the battery, components of the equivalent circuit model depending on determined internal state of the battery and the parameters of the offline model taking into account the equivalent circuit model;
ii) employing actual operational data, in an online data operational mode, for capturing various modes of operation of the battery and different discharge rates to fit the parameters of the offline model; and
iii) using a completed analysis from step ii) to enable the offline model to be used in an online phase to adjust estimates of the internal battery state as the battery is operating.

8. The computer system of claim 7, wherein for the offline model taking into account a particular discharge event D, a cumulative error for given parameters θ and initial state Q⁰ of offline model parameters θ and initial state Q⁰ is based on
$$Err ( D , θ , {Q}^{0} ) = {\sum }_{i = 1}^{N} \frac{1}{N} \frac{{( \hat{V} ( D , {t}_{i} ) - {V}_{D} ( {t}_{i} ) )}^{2}}{2} \\ \begin{matrix}\hat{V} ( D , t ) = {V}_{OC} ( S ( D , t ) ) - {R}_{s} ( S ( D , t ) , θ ) {I}_{D} ( t ) - \\ \frac{{Q}_{a} ( D , t )}{{C}_{p }^{a} ( S ( D , t ) , θ )} - \frac{{Q}_{b} ( D , t )}{{C}_{p}^{b} ( S ( D , t ) , θ )}\end{matrix} \\ \frac{d κ ( D , t )}{d t} = - \frac{{{I}_{0} ( \frac{{I}_{D} ( t )}{{I}_{0}} )}^{α}}{C} \\ S ( D , t ) = {I}_{r} \frac{κ C}{{{I}_{0} ( \frac{{I}_{r}}{{I}_{0}} )}^{α}} \frac{1}{{C}_{r}} \\ \frac{d {Q}_{a} ( D , t )}{d t} = {C}_{p}^{a} ( S ( D , t ) ) \frac{d ( {I}_{D} ( t ) {R}_{p}^{a} ( S ( D , t ) , θ ) )}{d t} \\ \frac{d {Q}_{b} ( D , t )}{d t} = {C}_{p}^{b} ( S ( D , t ) ) \frac{d ( {I}_{D} ( t ) {R}_{p}^{b} ( S ( D , t ) , θ ) )}{d t} \qquad ( 1 )$$
where the discharge event D consists of time series {(t, I_{D}(t), V_{D}(t)} of current and voltage measurements taken at discrete points in time t=t₁, t₂, . . . , t_{N}, θ denotes model parameters, S is a state of charge of the battery from the stored charge K, I represents current, V represents voltage, Iᵣ is a rated discharge current, R is resistance, C is capacitance, and Cᵣ is a rated capacitance, and Q⁰=[S⁰; Qₐ⁰; Q_{b}⁰]∈R³ is the initial S and charges on two capacitors.

9. The computer system of claim 8, wherein assuming that the interval between successive measurements tᵢ, tᵢ₊₁ is small, the invention can solve the above cumulative errors in closed form over (tᵢ, tᵢ₊₁) and simply works with the integrated discrete time dynamics, which makes the simulation a lot faster overall.

10. The computer system of claim 7, wherein the internal state of the battery comprises an optimization procedure that compares closed circuit voltage predictions from the model with actual voltage measurements and tunes the parameters of the model to minimize the difference between these two.

11. The computer system of claim 7, wherein the offline model comprises using a collection of discharge profiles {Dᵢ}ᵢ₌₁^{K}, collected from actual operational data, to identify model parameters θ by solving an optimization problem based on
$${min}_{θ , {Q}_{1}^{0} , {Q}_{2}^{0} , … , {Q}_{K}^{0}} {\sum }_{i} \frac{1}{K} Err ( {D}_{i} , θ , {Q}_{i}^{0} )$$
where Err ( [symbol] ᵢ, θ, Qᵢ⁰) represents gradients of error with respect to θ, Qᵢ⁰ and is computed using an adjoint method, [symbol] _{P} is the immediately preceding discharge profile corresponding to a last T minute of operation.

12. The computer system of claim 7, wherein the online data operational mode comprises an online state of charge SOC estimation entails a model that solves the following optimization problem:
$${min}_{{Q}^{0}} Err ( {D}_{p} , θ , {Q}^{0} ) ,$$
where Err ( [symbol] ᵢ, θ, Qᵢ⁰) represents gradients of error with respect to θ, Qᵢ⁰ and is computed using an adjoint method, [symbol] _{P} is the immediately preceding discharge profile corresponding to the last T minute of operation.
